(19) United States
(12) Patent Application Publication
(10) Pub. No.: US 2017/0077390 A1
(43) Pub. Date: Mar. 16, 2017

(54) SEMICONDUCTOR DEVICE WITH A MAGNETIC SHIELD

(71) Applicant: KABUSHIKI KAISHA TOSHIBA, Tokyo (JP)

(72) Inventor: Masashi OTSUKA, Fujisawa Kanagawa (JP)

(21) Appl. No.: 15/233,650

(22) Filed: Aug. 10, 2016

(30) Foreign Application Priority Data
Sep. 14, 2015 (JP) 2015-180895

(51) Int. Cl. H01L 43/02; H01L 27/22; H01L 43/12; H01L 43/08

(52) U.S. Cl. CPC H01L 43/02; H01L 43/08; H01L 27/226; H01L 43/12

(57) ABSTRACT

A semiconductor device includes a substrate, a magnetoresistive memory chip disposed on the substrate, and a sealing resin layer that seals the magnetoresistive memory chip. The magnetoresistive memory chip includes a magnetoresistive memory element layer and an organic resin layer that covers at least a portion of the magnetoresistive memory element layer and contains magnetic particles.

### CROSS-REFERENCE TO RELATED APPLICATION

This application is based upon and claims the benefit of priority from Japanese Patent Application No. 2015-180895, filed Sep. 14, 2015, the entire contents of which are incorporated herein by reference.

### FIELD

Embodiments described herein relate generally to a semiconductor device, in particular, a semiconductor device having magnetoresistive memory and a magnetic shield therefor.

### BACKGROUND

Various semiconductor memories have been developed, and are practically used today. Such semiconductor memories include a semiconductor memory using magnetism such as a magnetoresistive memory (Magnetoresistive Random Access Memory: MRAM). Since the magnetoresistive memory includes a memory element using magnetism, data held in the memory element may be lost due to influence of an external magnetic field. In order to suppress the influence of the external magnetic field, a semiconductor memory of one type includes a magnetic shield plate disposed on a semiconductor chip package of the magnetoresistive memory. However, such a magnetoresistive memory requires a process of disposing the magnetic shield plate, in addition to a process of stacking a plurality of semiconductor chips on a substrate when forming the semiconductor chip package. Moreover, the magnetic shield plate may not sufficiently shield the semiconductor chip package from the external magnetic field, especially, a semiconductor chip thereof that is located away from the magnetic shield plate.

### DESCRIPTION OF THE DRAWINGS

FIG. 1 is a schematic cross-sectional view of a semiconductor device according to an embodiment.

FIG. 2 is a schematic cross-sectional view of a magnetoresistive memory chip in the semiconductor device.

FIG. 3 is a schematic cross-sectional view of a portion of a chip stacked body in the semiconductor device.

FIG. 4 is a schematic cross-sectional view of the magnetoresistive memory chip according to another example.

FIG. 5 is a schematic cross-sectional view of a portion of the chip stacked body, illustrating two areas thereof.

### DETAILED DESCRIPTION

In general, according to an embodiment, a semiconductor device includes a substrate, a magnetoresistive memory chip disposed on the substrate, and a sealing resin layer that seals the magnetoresistive memory chip. The magnetoresistive memory chip includes a magnetoresistive memory element layer and an organic resin layer that covers at least a portion of the magnetoresistive memory element layer and contains magnetic particles.

Hereinafter, embodiments will be described with reference to the drawings. The drawings are schematic, and for example, a relationship between a thickness and a planar dimension, or a ratio of the thicknesses of the respective layers may be different from an actual value.

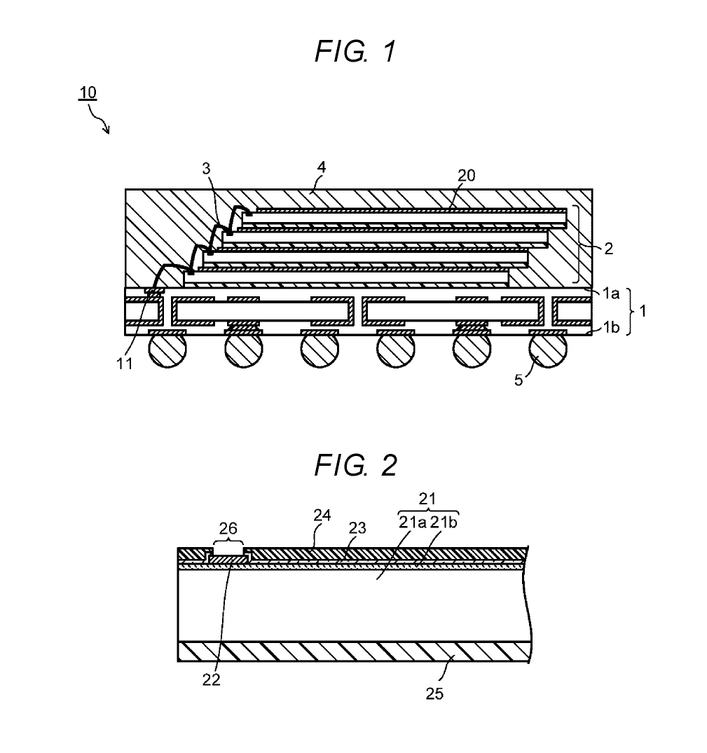

FIG. 1 is a schematic cross-sectional view of a semiconductor device. A semiconductor device 10 illustrated in FIG. 1 includes a substrate 1, a chip stacked body 2, a bonding wire 3, a sealing resin layer 4, and a conductor 5.

The substrate 1 includes a surface la and a surface lb, which is opposite to the surface la. FIG. 1 illustrates the surface la as an upper side and the surface lb as a lower side. As the substrate 1, for example, a wiring substrate where a wiring network is provided on a surface of an insulating resin substrate or in the insulating resin substrate is used. As the wiring substrate, for example, a printed wiring substrate (such as multilayer printed substrate) using glass epoxy resin or bismaleimide triazine resin (BT resin) is used.

The chip stacked body 2 includes a magnetoresistive memory chip 20 that is mounted on the substrate 1. For example, the magnetoresistive memory chip 20 is a memory chip including an MRAM. The magnetoresistive memory chip 20 illustrated in FIG. 1 has a four-stepped structure, but the number of magnetoresistive memory chips 20 is not particularly limited.

The bonding wire 3 is disposed on the substrate 1, and electrically connects an electrode 11 exposed on the surface 1a of the substrate 1 to the lowest of the magnetoresistive memory chips 20. The electrode 11 is electrically connected to the wiring network of the substrate 1. Furthermore, the bonding wire 3 electrically connects the plurality of magnetoresistive memory chips 20 to each other. For example, the bonding wire 3 contains gold, silver, copper, or aluminum.

The sealing resin layer 4 seals the magnetoresistive memory chip 20 and the bonding wire 3. The sealing resin layer 4 contains an inorganic filler (for example, SiO₂). For example, the sealing resin layer 4 is formed by a molding method such as a transfer molding method, a compression molding method or an injection molding method using a sealing resin which contains an inorganic filler, an organic resin, or the like.

The conductor 5 is disposed on the surface lb of the substrate 1, and is electrically connected to a connection pad which is exposed on the surface lb. The conductor 5 serves as an external connection terminal. For example, a signal, a power supply voltage, and the like are supplied to the magnetoresistive memory chip 20 through the external connection terminal. For example, the conductor 5 contains gold, copper, solder, or the like. As solder, for example, tin-silver based lead-free solder, tin-silver-copper based lead-free solder, or the like is used. The conductor 5 may include a plurality of stacked layers which are formed of metallic materials. The semiconductor device 10 illustrated in FIG. 1 includes the conductor 5 including a conductive ball, but may include the conductor 5 including a bump.

Next, a detailed structure of the magnetoresistive memory chip 20 will be described with reference to FIG. 2. FIG. 2 is a schematic cross-sectional view of the magnetoresistive memory chip 20. The magnetoresistive memory chip 20 illustrated in FIG. 2 includes a magnetoresistive memory element layer 21, an electrode 22, an insulating layer 23, an organic resin layer 24, and an organic bonding layer 25.

For example, the magnetoresistive memory element layer includes a memory cell that includes a plurality of magnetoresistive memory elements, a decoder that selects one or more of the magnetoresistive memory elements on which writing or reading of data is to be performed, a control circuit that controls an operation of the decoder, and a peripheral circuit that includes a power supply circuit which supplies power to the decoder and the control circuit. For example, a thickness of the magnetoresistive memory element layer 21 is between 30 μm and 80 μm.

For example, the magnetoresistive memory element layer includes a semiconductor element layer 21a and a magnetoresistive element layer 21b that is disposed on the semiconductor element layer 21a and includes a magnetoresistive element such as a magnetic tunnel junction (MTJ) element. For example, the semiconductor element layer 21a includes an insulating layer, a conductive layer, or the like on a semiconductor substrate such as a silicon substrate.

Furthermore, for example, the semiconductor element layer 21a includes a memory cell portion that includes a first transistor, and a peripheral circuit portion that includes a semiconductor element which includes a second transistor. The first transistor controls a supply of charges to the magnetoresistive element. The second transistor is one of elements configuring the peripheral circuit. For example, the magnetoresistive element is disposed on the memory cell portion of the semiconductor element layer 21a, and is electrically connected to an input/output terminal of the first transistor through a wiring or the like.

The electrode 22 is disposed on the magnetoresistive element layer 21b. For example, the electrode 22 is electrically connected to the semiconductor element configuring the peripheral circuit of the semiconductor element layer 21a. The electrode 22 serves as an electrode pad. For example, the electrode 22 contains copper, silver, gold, aluminum, or the like. For example, the electrode 22 may include a plated film which contains the above material and is formed by a sputtering method, an electrolytic plating method, an electroless plating method or the like.

The insulating layer 23 is disposed on the magnetoresistive memory element layer 21, and on a portion of the electrode 22. For example, the insulating layer 23 contains a silicon oxide or a silicon nitride. For example, the insulating layer 23 serves as a passivation layer.

The organic resin layer 24 is provided so as to cover at least a portion of the magnetoresistive memory element layer 21. The organic resin layer 24 illustrated in FIG. 2 is provided so as to cover the magnetoresistive element layer 21b with the insulating layer 23 therebetween. The organic resin layer 24 serves as a passivation layer. For example, the organic resin layer 24 contains polyimide.

Furthermore, the organic resin layer 24 contains magnetic powder (particles). The organic resin layer 24 containing the magnetic powder (particles) serves as a magnetic shield layer. The organic resin layer 24 is not necessarily provided.

For example, the organic resin layer 24 is formed by applying a liquid organic resin which contains the magnetic particles by a spin coating method. For example, the thickness of the organic resin layer 24 is between 2 μm and 5 μm.

The insulating layer 23 and the organic resin layer 24 include an opening 26 which exposes at least a portion of the electrode 22. The organic resin layer 24 may be selectively processed through an etching using the exposed and developed photoresist.

The organic bonding layer 25 is provided so as to cover at least a portion of the magnetoresistive memory element layer 21. The organic bonding layer 25 illustrated in FIG. 2 is in contact with an opposite surface of the magnetoresistive memory element layer 21 to a formation surface on which the magnetoresistive element layer 21b is formed. As an organic bonding layer 25, for example, a die attach film (DAF) or the like is used. As the DAF, for example, an adhesive sheet including an epoxy resin, a polyimide resin, an acrylic resin or the like as a main ingredient is used.

Furthermore, the organic bonding layer 25 contains the magnetic particles. The organic bonding layer 25 containing the magnetic particles serve as a magnetic shield layer. At least one of the organic resin layer 24 and the organic bonding layer 25 may contain the magnetic particles.

As the magnetic particles, for example, soft magnetic metal such as iron (Fe), nickel (Ni) or cobalt (Co), or a soft magnetic alloy containing at least one of the above soft magnetic metals is used. As a soft magnetic alloy, silicon steel (Fe—Si), carbon steel (Fe—C), permalloy (Fe—Ni), sendust (Fe—Si—Al), permendur (Fe—Co), ferrite stainless or the like is used. The organic resin layer 24 and the organic bonding layer 25 may contain the same magnetic particles. Alternatively, the organic resin layer 24 and the organic bonding layer 25 may contain different magnetic particles.

It is easier to prepare the organic resin layer 24 and the organic bonding layer 25 that contain the magnetic particles in comparison with preparing the sealing resin layer 4 that contains the magnetic particles. Accordingly, for example, a content of the magnetic particles per unit volume in the organic resin layer 24 or the organic bonding layer 25 can be made larger in comparison with the sealing resin layer 4.

The magnetoresistive memory chips 20 are stacked in a multistep manner so as to expose the electrode 22. The magnetoresistive memory chips 20 which are stacked in the multistep manner are bonded to each other in sequence through the organic bonding layer 25. The electrodes 22 of the magnetoresistive memory chips 20 which are stacked in the multistep manner are electrically connected to each other in sequence through the bonding wire 3. Moreover, the electrode 22 of the lowest of the magnetoresistive memory chip 20 is electrically connected to the electrode 11 which is disposed on the surface 1a of the substrate 1 through the bonding wire 3.

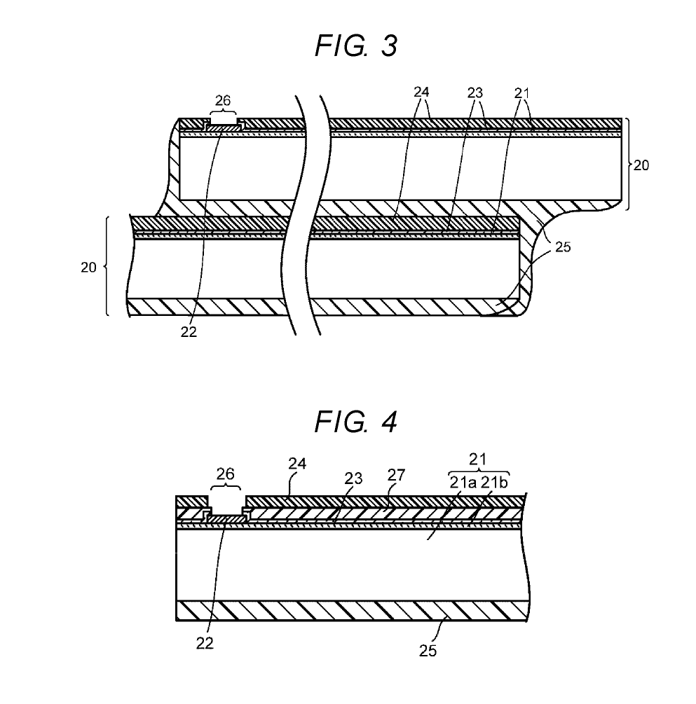

If the plurality of magnetoresistive memory chips 20 which is stacked in the multistep manner is bonded to each other by the organic bonding layer 25 such as the die attach film, a heat treatment is performed after the plurality of magnetoresistive memory chips 20 is stacked. Through this process, the magnetoresistive memory chips 20 are bonded to each other, and the magnetoresistive memory chip 20 is bonded to the substrate 1 by temporarily softening the organic bonding layer 25. At this time, as illustrated in FIG. 3, the organic bonding layer 25 may flow along a side surface of the magnetoresistive memory element layer 21. FIG. 3 is a schematic cross-sectional view of the chip stacked body 2 for describing a bonding state of the magnetoresistive memory chips 20.

The organic bonding layer 25 illustrated in FIG. 3 covers the side surface of the magnetoresistive memory element layer 21, and is in contact with the organic resin layer 24. Furthermore, the organic bonding layers 25 of the magnetoresistive memory chips 20 which are stacked in the multistep manner are in contact with each other so as to cover the side surface of the magnetoresistive memory element layer 21. By arranging the organic bonding layer 25 so as to cover the side surface of the magnetoresistive memory element layer 21, the bonding strength between the organic resin layer 24 and the organic bonding layer 25 is enhanced. Therefore, in case where the organic resin layer 24 is in contact with the organic bonding layer 25, since the magnetic force applied to the organic resin layer 24 is likely to be transmitted to the organic bonding layer 25, and the magnetic force applied to the organic bonding layer 25 is likely to be transmitted to the organic resin layer 24. As a result, an effect of suppressing influence of a magnetic field in a vertical direction is enhanced. Moreover, since the influence of the magnetic field in a horizontal direction may be suppressed by including the magnetic particles in the organic bonding layer 25, it is possible to further enhance a magnetic shield effect of the magnetoresistive memory chip 20.

The semiconductor device of the present embodiment is provided so as to cover at least a portion of the magnetoresistive memory chip, and includes at least one organic resin layer containing the magnetic particles and the organic bonding layer. The organic resin layer containing the magnetic particles and the organic bonding layer are provided for each magnetoresistive memory chip. In this manner, since the organic resin layer containing the magnetic particles and the organic bonding layer may be disposed in a position which is very close to the magnetoresistive memory chip, it is possible to enhance the magnetic shield effect. Moreover, it is possible to form a magnetic shield layer by including the magnetic particles in the organic resin layer or the organic bonding layer. Accordingly, it is possible to suppress an increase in the number of manufacturing processes in comparison with a case where a magnetic shield plate is separately stacked on the magnetoresistive memory chip.

The structure of the magnetoresistive memory chip 20 is not limited to the structure illustrated in FIG. 2. FIG. 4 is a schematic cross-sectional view of the magnetoresistive memory chip 20 according to another example. The magnetoresistive memory chip 20 illustrated in FIG. 4 is different from the magnetoresistive memory chip 20 illustrated in FIG. 2 at least in that an organic protective layer 27 is disposed between the magnetoresistive memory element layer 21 and the organic resin layer 24. For the components that are the same as the components illustrated in FIG. 2, the description will be omitted.

The organic protective layer 27 is disposed on the insulating layer 23. The organic resin layer 24 is disposed on the organic protective layer 27. The organic protective layer 27 protects the magnetoresistive memory element layer 21. For example, the organic protective layer 27 contains polyimide or the like.

Since the magnetoresistive memory element layer 21 is protected by the organic protective layer 27, it is possible to increase the content of the magnetic particles in the organic resin layer 24. Accordingly, it is possible to further enhance the magnetic shield effect.

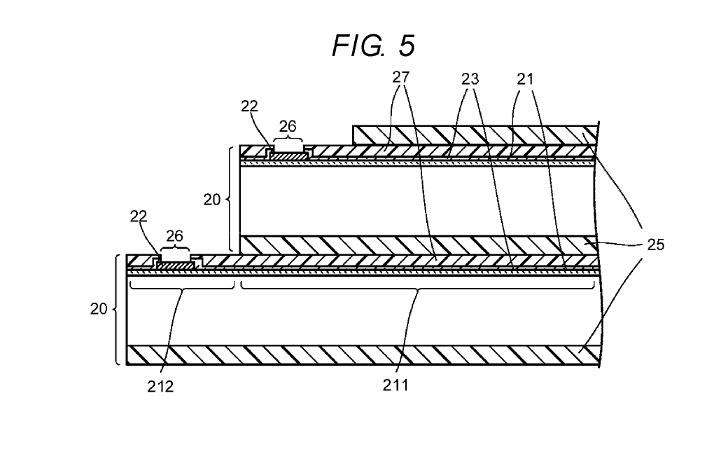

FIG. 5 is a schematic cross-sectional view of a portion of the chip stacked body 2. The bonding wire 3 is not illustrated in FIG. 5 for the sake of convenience. The magnetoresistive memory chip 20 illustrated in FIG. 5 is different from the magnetoresistive memory chip 20 illustrated in FIG. 2 at least in that the former one includes the organic protective layer 27 instead of the organic resin layer 24. That is, the magnetoresistive memory chip 20 illustrated in FIG. 5 includes the magnetoresistive memory element layer 21, the electrode 22 on the magnetoresistive memory element layer 21, the insulating layer 23 on the magnetoresistive memory element layer 21 and on the electrode 22, the organic protective layer 27 on the insulating layer 23, and the organic bonding layer 25 that is provided so as to cover at least a portion of the magnetoresistive memory element layer 21 which includes the opening 26 exposing a portion of the electrode 22, and contains the magnetic particles.

The magnetoresistive memory chips 20 are stacked in the multistep manner so as to expose the electrodes 22. The magnetoresistive memory chips 20 which are stacked in the multistep manner are bonded to each other in sequence through the organic bonding layer 25. At this time, the chip stacked body 2 may not include the organic bonding layer 25 in the uppermost magnetoresistive memory chip. The electrodes 22 of the magnetoresistive memory chips 20 which are stacked in the multistep manner are electrically connected to each other in sequence. Moreover, the electrode 22 of the lowest magnetoresistive memory chip is electrically connected to the electrode 11 which is disposed in the substrate 1.

The magnetoresistive memory element layer 21 includes an area 211 on which the organic bonding layer 25 is overlapped, and an area 212 on which the organic bonding layer 25 is not overlapped. The magnetic shield effect of the area 212 on which the organic bonding layer 25 containing the magnetic particles is not overlapped becomes low in comparison with the area 211. To effectively protect the chip stacked body 2 from the external magnetic field, the magnetoresistive memory element which is susceptible to the external magnetic field in comparison with the peripheral circuit is disposed in the area 211. That is, by disposing the memory cells within the area 211, it is possible to suppress the loss of data written in the magnetoresistive memory element.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate;
a magnetoresistive memory chip disposed on the substrate; and
a sealing resin layer that seals the magnetoresistive memory chip, wherein
the magnetoresistive memory chip includes a magnetoresistive memory element layer and an organic resin layer that covers at least a portion of the magnetoresistive memory element layer and contains magnetic particles.

2. The semiconductor device according to claim 1, wherein
the magnetoresistive memory chip further includes an organic protective layer disposed between the magnetoresistive memory element layer and the organic resin layer.

3. The semiconductor device according to claim 2, wherein
the magnetoresistive memory chip further includes an organic bonding layer containing magnetic particles, on a surface of the magnetoresistive memory chip that is opposite a surface on which organic resin layer is disposed.

4. The semiconductor device according to claim 1, wherein
the organic resin layer is disposed on a surface of the magnetoresistive memory chip opposite to a surface thereof that faces the substrate.

5. The semiconductor device according to claim 4, wherein
the magnetoresistive memory chip further includes an electrode that is electrically connected to a wiring on the substrate and exposed through an opening formed in the organic resin layer.

6. The semiconductor device according to claim 1, further comprising:
a second magnetoresistive memory chip overlapping the magnetoresistive memory chip with an offset, the second magnetoresistive memory chip including a magnetoresistive memory element layer and an organic resin layer that covers at least a portion of the magnetoresistive memory element layer of the second magnetoresistive memory chip and contains magnetic particles.

7. The semiconductor device according to claim 6, wherein
the organic resin layer of the magnetoresistive memory chip is disposed between the magnetoresistive memory element layer of the magnetoresistive memory chip and the second magnetoresistive memory chip.

8. The semiconductor device according to claim 7, wherein
the magnetoresistive memory element layer of the magnetoresistive memory chip includes a memory element portion in a region that overlaps with the second magnetoresistive memory chip and a peripheral circuit portion,
the memory element portion includes a memory element, and
the peripheral circuit portion includes a transistor that drives the memory element, at least part of the peripheral circuit portion not overlapping with the second magnetoresistive memory chip.

9. A semiconductor device, comprising:
a substrate;
a plurality of magnetoresistive memory chips bonded to the substrate and to each other with an organic bonding layer that contains magnetic particles; and
a sealing resin layer that seals the magnetoresistive memory chip.

10. The semiconductor device according to claim 9, wherein
each of the magnetoresistive memory chips further includes an organic resin layer on a surface thereof facing away from the substrate, the organic resin layer containing magnetic particles.

11. The semiconductor device according to claim 10, wherein
each of the magnetoresistive memory chips further includes a magnetoresistive memory element layer between the organic resin layer and the organic bonding layer.

12. The semiconductor device according to claim 9, wherein
the magnetoresistive memory chips include a first magnetoresistive memory chip disposed on the substrate and a second magnetoresistive memory chip disposed on the first magnetoresistive memory chip with an offset.

13. The semiconductor device according to claim 12, wherein
the first magnetoresistive memory chip includes a memory element portion in a region that overlaps with the second magnetoresistive memory chip and a peripheral circuit portion,
the memory element portion includes a memory element, and
the peripheral circuit portion includes a transistor that drives the memory element, at least part of the peripheral circuit portion not overlapping with the second magnetoresistive memory chip.

14. A method for magnetically shielding a magnetoresistive memory device, comprising:
forming an organic bonding layer that contains magnetic particles, on a surface of each of a plurality of magnetoresistive memory chips;
stacking the plurality of magnetoresistive memory chips with an offset, such that an electrode formed on a top surface of each of the magnetoresistive memory chips is exposed; and
heating each of the organic bonding layers to bond the magnetoresistive memory chips to each other and a lowermost magnetoresistive memory chip to a substrate.

15. The method according to claim 14, wherein each of the magnetoresistive memory chips includes an organic resin layer on a surface thereof facing away from the substrate, the organic resin layer containing magnetic particles.
